(19) United States
(12) Patent Application Publication
(10) Pub. No.: US 2016/0153109 A1
(43) Pub. Date: Jun. 2, 2016

(54) CASING OF ELECTRONIC DEVICE AND MANUFACTURING METHOD THEREOF

(71) Applicant: HTC Corporation, Taoyuan City (TW)

(72) Inventors: Chih-Sheng Wei, Taoyuan City (TW); Shih-Ying Peng, Taoyuan City (TW); Cheng-Han Chung, Taoyuan City (TW); Tsung-Yuan Ou, Taoyuan City (TW)

(73) Assignee: HTC Corporation, Taoyuan City (TW)

(21) Appl. No.: 14/556,015

(22) Filed: Nov. 28, 2014

(51) Int. Cl. C25D 11/02; H05K 5/02; C25D 7/00; A45C 11/00; B05D 5/02

(52) U.S. Cl. CPC C25D 11/02; A45C 11/00; B05D 5/02; C25D 7/00; H05K 5/0243

(57) ABSTRACT

A casing of an electronic device and a manufacturing method thereof are provided. The casing comprises a metal shell, a painting layer and a micro-arc oxidation (MAO) layer. The MAO layer is formed between the metal shell and the painting layer.

### TECHNICAL FIELD

The disclosure relates in general to a casing of an electronic device and a manufacturing method thereof, and more particularly to a casing of an electronic device with an MAO layer and a manufacturing method thereof.

### BACKGROUND

Conventional casing of an electronic device normally performs surface treatment by using anode processing. The anode processed casing provides superior surface touch and visual effect. Anode processing is ideally used on pure aluminum. However, nowadays the casing material comprises metals other than aluminum, and it becomes very difficult to perform anode processing treatment on the surface of the casing.

Therefore, how to resolve the above problems to obtain a casing whose surface is anode possessed has become a prominent task for the industries.

### SUMMARY

The invention is directed to a casing of an electronic device and a manufacturing method thereof, in which the casing has a surface similar or identical to an anode surface treatment.

According to one embodiment of the invention, a casing of an electronic device is provided. The casing comprises a metal shell, a painting layer and a micro-arc oxidation (MAO) layer. The MAO layer is formed between the metal shell and the painting layer.

According to another embodiment of the invention, a method for manufacturing a casing of an electronic device is provided. The manufacturing method comprises following steps of forming a metal shell; forming an MAO layer on the metal shell by using an MAO process; and forming a painting layer on the MAO layer in a paint spraying process.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1A is an appearance diagram of a casing of an electronic device according to an embodiment of the invention.

FIG. 1B is a cross-sectional view of the casing of FIG. 1A along direction 1B-1B′.

FIGS. 2A to 2B are manufacturing processes of the casing of FIG. 1A.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

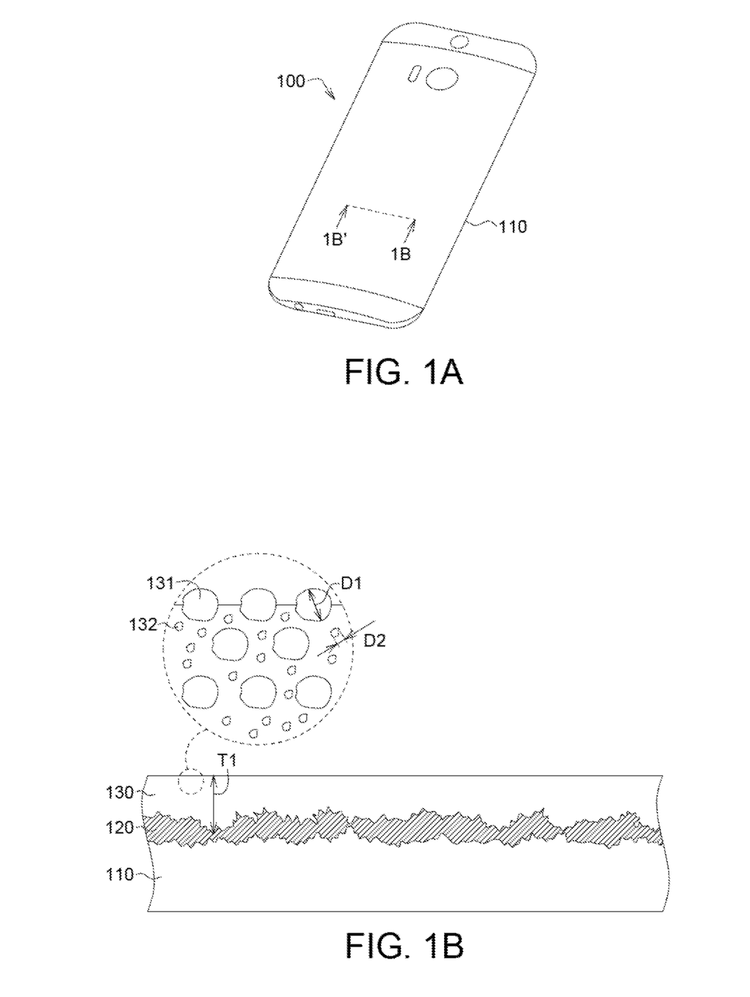

Refer to FIGS. 1A and 1B. FIG. 1A is an appearance diagram of a casing of an electronic device according to an embodiment of the invention. FIG. 1B is a cross-sectional view of the casing of FIG. 1A along direction 1B-1B′.

The casing 100 is a casing of an electronic device, wherein the electronic device can be such as a mobile phone, a computer, an audio player, a video player and so on. The casing 100 comprises a metal shell 110, a micro-arc oxidation (MAO) layer 120 and a painting layer 130.

In respect of material, the material of the metal shell 110 may comprise aluminum, magnesium, zinc, titanium, copper or a combination thereof. The metal shell 110 does not need to consider whether its material composition or component proportion is applicable to anode processing or not. In respect of the manufacturing process, the metal shell 110 can be formed by using die casting, forging, stamping, cutting or other mechanical shaping methods.

The MAO layer 120 is formed between the metal shell 110. In the present embodiment, the MAO layer 120 is directly formed on the metal shell 110, that is, there is no other layer structure between the MAO layer 120 and the metal shell 110. In an embodiment, the MAO layer 120 can be a ceramic oxidation layer formed by applying the MAO process to oxidize the surface of the metal shell 110. The ceramic oxidation layer has good hardness which provides better protection for the metal shell 110. The MAO layer 120 is formed between the metal shell 110 and the painting layer 130 as a bonding layer. Furthermore, the MAO layer 120 has a porous rough ceramic structure enabling the painting layer 130 to be tightly formed on the MAO layer 120. Under such design, the bonding between the painting layer 130 and the metal shell 110 can be enhanced through the disposition of the MAO layer 120. Furthermore, the MAO layer 120 can be used as a medium layer of the painting layer 130.

The MAO layer 120 has a thickness between about 5 μm and 50 μm, such that the requirements of appearance and performance reliability are satisfied, and the design space is more flexible. In an embodiment, the color of the MAO layer 120, such as light color, light gray color or white color, can be used as a ground color of the painting layer 130 for shielding the defects on the surface of the metal shell 110. Under the design that the light gray color or white color is used as the background color, the painting layer 130 formed on the MAO layer 120 can have more choices of colors. Besides, under the design that the light gray color or white color is used as the background color, even when the painting layer 130 is very thin, the visual color that the painting layer 130 aims to provide will not be or will only be lightly affected by the background color of the MAO layer 120. In another embodiment, the MAO layer 120 can have a dark color such as black.

The painting layer 130 is formed on the MAO layer 120, and comprises a plurality of tactile particles 131 and a plurality of colorant particles 132. The outer diameter D1 of each tactile particle 131 is greater than the outer diameter D2 of each colorant particle 132 such that the painting layer 130 can provide a particular touch. For example, the outer diameter D1 of each tactile particle 131 is between 10 μm and 60 μm, such that the painting layer 130 can provides a sandblasting touch similar to the touch provided by anode surface treatment.

The painting layer 130 can be realized by a single-layered structure or a multi-layered structure. In respect of the single-layered structure, the painting layer 130 can be formed in one-time paint spraying process. Since the thickness T1 of the painting layer 130 is very small, a low thermal resistance between the painting layer 130 and the metal shell 110 can be achieved, and the painting layer 130 can provide a low-temperature touch similar to the touch provided by an anode surface treatment. In an embodiment, the painting layer 130 has a thickness T1 ranging between about 5 μm and 20 μm. In respect of the multi-layered structure, the painting layer 130 can be formed in several times of the paint spraying process. Since the total thickness of the multi-layered painting 130 is between about 5 μm and 20 μm, the painting layer 130 can provide a low-temperature touch similar to the touch provided by anode surface treatment.

Besides, the more the number of times of spray, the more difficult the control of spray volume and spray quality will be. In the embodiments of the invention, the painting layer 130 is formed in one-time paint spraying process, so the control of the spray volume and spray quality of the painting layer 130 is easy, and the painting layer 130 can avoid or reduce aesthetic problems such as sagging, fat edges and wrinkles.

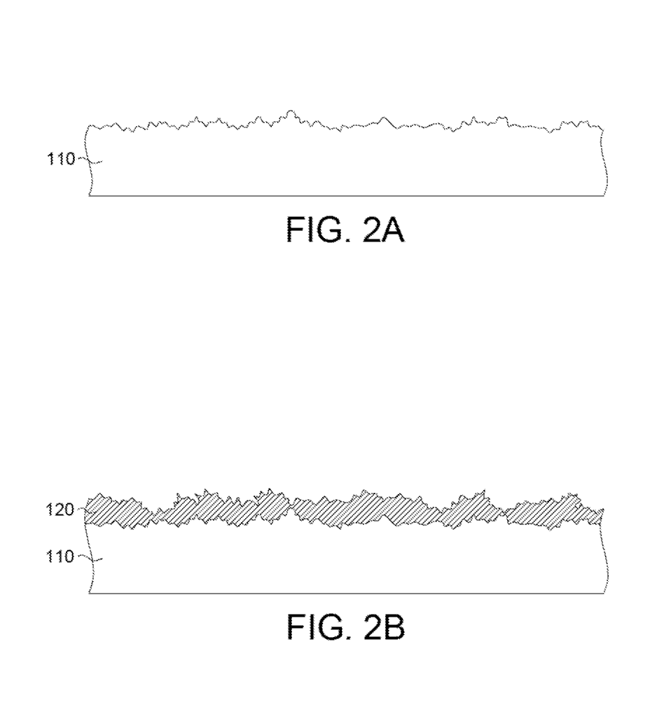

Referring to FIGS. 2A to 2B, manufacturing processes of the casing of FIG. 1A are shown.

As indicated in FIG. 2A, the metal shell 110 can be formed by using a mechanical process. The material of the metal shell 110 comprises aluminum, magnesium, zinc, titanium or a combination thereof, and the mechanical process is such as die casting process, forging process, stamping process, cutting process or other mechanical shaping process.

As indicated in FIG. 2B, the MAO layer 120 can be formed on the metal shell 110 by using such as a micro-arc oxidation (MAO) process. In the present embodiment, after the metal shell 110 is formed, film processing is not performed on the metal shell 110 (normally, film processing is performed on the die casted product after die casting is completed), and the MAO process is immediately performed on the metal shell 110 to form the MAO layer 120 on the metal shell 110 directly. In another embodiment, before the MAO layer 120 is formed, other surface treatment can be performed on the metal shell 110 prior to the formation of the MAO layer 120. Under such design, the MAO layer 120 is indirectly formed on the metal shell 110.

Then, in one-time paint spraying process, the painting layer 130 of FIG. 1B is formed on the MAO layer 120. At this point, the formation of the casing 100 is completed.

Here, “one-time paint spraying process” refers to the situation that the entire painting layer 130 is finished in one-time paint spraying process, and the number of the paint spraying process is limited to one. In comparison to the conventional painting layer, being a multi-layered structure, the painting layer 130 of the embodiments of the invention, being a single-layered structure, is thinner and has lower thermal resistance between the painting layer 130 and the metal shell 110, and the casing 100 can provide a low-temperature touch. Thus, when the user touches the casing, the user can feel the tactility of the metal shell 110 instead of feeling blocked by the painting layer 130.

Since the painting layer 130 of the embodiments of the invention is completed in one-time paint spraying process, the control of the paint volume and spray quality of the painting layer 130 is made easier and the painting layer 130 can avoid or reduce aesthetic problems such as sagging, fat edges and wrinkles.

Besides, the painting layer 130 comprises a plurality of tactile particles 131 and a plurality of colorant particles 132. The colorant particles 132 have a color (such as silver, black, white, red or other colors) and provide a color appearance for the casing 100a. In the present embodiment, since each tactile particle 131 has an outer diameter D1 ranging between 10 μm and 60 μm, the painting layer 130 is capable of providing a sliding touch similar to that provided by anode surface treatment.

In another embodiment, other process can be performed on the casing 100 of FIG. 1B. For example, a mechanical process (such as drilling process) can be performed on the casing 100; or, other process can be performed in accordance with the design of the electronic device.

To summarize, the casing of an electronic device and the manufacturing method thereof disclosed in above embodiments of the invention at least provide have following effects:

(1). In an embodiment, the painting layer comprises a plurality of tactile particles and is capable of providing a sliding touch similar to that provided by anode surface treatment.

(2). In an embodiment, the painting layer has a small thickness and is capable of reducing the thermal resist between the painting layer and the metal shell and enabling the casing to provide a low-temperature touch.

(3). In an embodiment, the painting layer is formed in one-time paint spray process, therefore the paint volume and spray quality can be better controlled, and aesthetic problems such as sagging, fat edges and wrinkles can be avoided or reduced.

(4). In an embodiment, the MAO layer is formed between the metal shell and the painting layer, therefore the bonding between the painting layer and the metal shell can be enhanced through the disposition of the MAO layer despite of the poor bonding between the painting layer and the metal shell.

(5). In an embodiment, the MAO layer is realized by a ceramic oxidation layer with good hardness which provides better protection for the metal shell.

(6). In an embodiment, if the painting layer has poor corrosion resistance, the disposition of the MAO layer can compensate such drawback and enhance the overall corrosion resistance of the casing.

(7). In an embodiment, if the painting layer cannot well shield the color of the metal shell, the MAO layer can shield the color defects of the metal shell. In addition, the MAO layer can provide a light ground color to mitigate the influence generated by the color of the painting layer.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A casing of an electronic device, comprising:
a metal shell;
a painting layer; and
a micro-arc oxidation (MAO) layer formed between the metal shell and the painting layer.

2. The casing according to claim 1, wherein the MAO layer is directly formed on the metal shell.

3. The casing according to claim 1, wherein the painting layer comprises a plurality of tactile particles.

4. The casing according to claim 3, wherein the painting layer further comprises a plurality of colorant particles, and an outer diameter of each tactile particle is greater than that of each colorant particle.

5. The casing according to claim 3, wherein each tactile particle has an outer diameter ranging between 10 μm and 60 μm.

6. The casing according to claim 1, wherein the painting layer has a thickness ranging between 5 μm and 20 μm.

7. The casing according to claim 1, wherein the MAO layer has a thickness ranging between 5 μm and 50 μm.

8. The casing according to claim 1, wherein the metal shell is made of a material comprising aluminum, magnesium, zinc, titanium, copper or a combination thereof.

9. The casing according to claim 1, wherein the color of the MAO layer is white.

10. The casing according to claim 1, wherein the painting layer is a single-layered structure.

11. A method for manufacturing a casing of an electronic device, comprising:
forming a metal shell;
forming an MAO layer on the metal shell by using an MAO process; and
forming a painting layer on the MAO layer in a paint spraying process.

12. The manufacturing method according to claim 11, wherein the step of forming the metal shell is completed by die-casting or forging.

13. The manufacturing method according to claim 11, wherein after the step of forming the metal shell, the step of forming the MAO layer on the metal shell is directly performed.

14. The manufacturing method according to claim 11, wherein the painting layer comprises a plurality of tactile particles.

15. The manufacturing method according to claim 14, wherein the painting layer further comprises a plurality of colorant particles, and an outer diameter of each tactile particle is greater than that of each colorant particle.

16. The manufacturing method according to claim 14, wherein each tactile particle has an outer diameter ranging between 10 μm and 60 μm.

17. The manufacturing method according to claim 11, wherein the painting layer has a thickness ranging between 5 μm and 20 μm.

18. The manufacturing method according to claim 11, wherein the MAO layer has a thickness ranging between 5 μm and 50 μm.

19. The manufacturing method according to claim 11, wherein the color of the MAO layer is white.

20. The manufacturing method according to claim 11, wherein the paint spraying process is performed only once, and the painting layer is a single-layered structure.
